(19) United States
(12) Patent Application Publication
(10) Pub. No.: US 2009/0158947 A1
(43) Pub. Date: Jun. 25, 2009

(54) Stamp Comprising a Nanostamping Structure, Device and Method for the Production Thereof

(76) Inventor: Erich Thallner, St Florian (AT)

Correspondence Address: KUSNER & JAFFE;HIGHLAND PLACE SUITE 310, 6151 WILSON MILLS ROAD, HIGHLAND HEIGHTS, OH, 44143, US

(21) Appl. No.: 11/991,940

(22) PCT Filed: Sep. 2, 2006
(86) PCT No.: PCT/EP2006/008582

§ 371 Date: Mar. 12, 2008

(30) Foreign Application Priority Data
Sep. 14, 2005 (EP) 05019943.9

(51) Int. Cl. B41D 7/04; G03F 7/00

(52) U.S. Cl. 101/333; 430/252

(57) ABSTRACT

The invention relates to a stamp comprising a nanostructure for introducing and/or applying nanostructures into/onto components as well as a device and a method for producing said stamp. The inventive stamp is provided with a rigid support for the nanostamping structure while the nanostamping structure is joined to the support.

The present invention relates to a stamp comprising a nanostamping structure for introducing and/or applying nanostructures to components, as well as a device and a method for the production of the stamp, wherein the stamp comprises a rigid support for the nanostamping structure and the nanostamping structure is joined to the support, and wherein the nanostamping structure comprises raised structures and depressions adjacent to the raised structures.

In the semiconductor industry it is necessary to transfer very small structures to for example wafers, metals, plastics or similar materials and components.

It is generally known in the prior art to produce these structures by means of photolithography. To this end the wafers or the other components are coated with a photoresist and then illuminated by means of suitable illumination devices. The structures are formed in a subsequent development process.

A further possible way of producing nanostructures is by so called writing methods by means of electron beam devices or ion beam writers. The production of nanostructures by means of X-radiation is also known.

More recent methods use stamping or embossing processes for applying nanostructures to component surfaces. In the so-called stamping method flexible stamps of poly(dimethyl-siloxane) (PDMS) are used. This technology is described for example in the printed specifications US 2004/0011231 A1, U.S. Pat. No. 5,817,242 as well as WO 2003/099463 A3.

In the known embossing techniques the maximum possible structure transfer region is small. Typically the size of this region is about 625 mm² and is therefore unsuitable for producing large, two-dimensional regions, such as for example data storage media.

02/42844 A2 describes a stamp for introducing structures into components, wherein the stamp structure, which comprises patterns in the micrometre and/or sub-micrometre range, is directly joined to the support. The described stamp comprises structures in the range from 1-100 μm, which on account of the softness of the structure material, for example PDMS, and the stamp thickness, scarcely permit an image of the stamp structure in the sub-micrometre range, since horizontal displacements and thus an inaccurate reproduction of the structure occur. The formation of an image in the sub-micrometre range is therefore not possible with the desired precision using this device, especially since the planarity of the wafer surfaces in the nanometre range is not exact on account of pre-treatment steps.

The object of the invention is accordingly to provide a stamp with a nanostructure as well as a device and a method for the production thereof, with which large-area nanostructures can be applied in a precise manner to component surfaces.

This object is achieved by the features of claims 1, 11 and 27.

The invention is based on the idea of joining the nanostamping structure to a rigid support and in this way, by forming the depressions as far as possible close up to the rigid support, to largely avoid an interaction between adjacent raised structures. At the same time the aim is to achieve as close and intimate a connection as possible between the nanostamping structure and the support. Due to the configuration according to the invention horizontally acting forces and displacements of the stamp structure resulting therefrom are largely avoided, with the result that it is possible to obtain a very precise image of the stamp structure.

In other words, due to the measure of forming the depressions extending predominantly up to the rigid support, flexible connections between the raised structures are largely excluded.

A precise image is achieved by greatly reducing the stamp thickness, in particular the ratio between the height of the raised structures and the overall height of the nanostamping structure, which is as small as possible and preferably tends to zero.

In contrast to the known, flexible PDMS stamps, in the case of the stamp according to the invention with a rigid support it is possible to form nanostructures over a large surface area without any so-called “run out”. The disadvantage of the known flexible stamps, of deforming during the stamping process, which leads to distortions and deformations in the nanostructure to be introduced/applied, is advantageously avoided. The stamp according to the invention is therefore particularly suitable for the application of nanostructures to solid plate-type storage discs, for flat panel structuring as well as for applying nanostructures to wafers in so-called full wafer structuring processes. The stamp according to the invention can however also be used for the application of nanostructures to smaller surfaces, for example in the so-called step and repeat process.

In a development of the invention it is advantageously envisaged that the nanostamping structure of the stamp consists of a hardened polymer. Elastomers, preferably siloxanes, are particularly suitable for this purpose. The nanostamping structure advantageously consists of hardened poly(dimethylsiloxane) (PDMS).

In order to produce a particularly intimate connection between the nanostamping structure and the support, it is of decisive advantage if the support consists, at least in a partial region, of porous material and/or material penetrated by channels, wherein a pore size of between 10 and 100 μm is particularly advantageous. In the production of the stamp the still liquid polymer can penetrate into the pores and/or channels or capillaries of the support. In the production of the stamp a vacuum in particular is applied for this purpose to the support, in order to aspirate the liquid polymer in a defined manner. The nanostructure is firmly embedded in the support once the polymer has hardened. It is also conceivable, in addition or alternatively, to force or press the liquid polymer into the pores and channels by means of excess pressure. A further substantial advantage of the special configuration of the support is that the support can be wetted in a subsequent stamping process with inwardly diffusing substances, such as for example thiols or proteins. The support, which is porous or penetrated by channels, aspirates these substances completely and releases them via the nanostamping structure in the stamping process to the substrate to be structured, for example a noble metal. There is therefore no longer any need to carry out a wetting before each stamping process. The support acts as a reservoir for these substances.

Ceramic materials of very small grain size are particularly suitable as materials for producing the support. The ceramic material is advantageously a sintered ceramic material.

In order to be able to accurately adjust the stamp according to the invention to the substrate to be structured, in a development of the invention adjustment means are provided. It is possible for example to fasten electrically or electronically detectable media or materials to the stamp or integrate them into the latter, in particular into the support material. Coloured or fluorescing substances or substances that change under specific physical conditions can also be used as adjustment means.

Advantageously the adjustment means are arranged on the side of the support facing the nanostamping structure. In this way it is possible to adjust the stamp from the side facing the nanostamping structure.

In a development of the invention it is advantageously envisaged that the adjustment means are formed as three-dimensional adjustment markers. Advantageously the adjustment markers are applied to the support during the production of the nanostamping structure, whereby after a measurement step an accurately defined allocation is given to the nanostamping structure of the stamp. Optical or mechanical adjustment systems are particularly suitable for adjusting the stamp to the substrate to be structured. For example, the adjustment markers can be scanned mechanically by means of AFM needles.

Preferably the adjustment markers are produced according to the same principle as the nanostamping structure. The adjustment markers advantageously consist of a hardened polymer, in particular an elastomer, preferably a siloxane, and most preferably consist of PDMS. The material for the adjustment markers need not necessarily be identical to the material for the production of the nanostamping structure.

The device according to the invention for the production of the stamp includes according to the invention a receiving means for receiving a rigid support. The supports are as a rule formed as flat plates with two oppositely facing, flat and also parallel side faces. The device according to the invention also includes at least one master stamp, movable relative to the rigid support, with a nanostructure surface. It is furthermore envisaged in a modification of the invention to integrate in the device at least one application means for applying a flowable, hardenable polymer, in particular an elastomer, preferably a siloxane, specifically PDMS, to the support and/or to the master stamp. The application means are preferably designed as nozzles.

First of all a rigid support is introduced, preferably inserted or placed, in the receiving means. The flowable polymer is then applied by means of the application means, for example to the surface of the rigid support. This is followed by a relative movement between the master stamp and support in such a way that the nanostructure surface of the master stamp dips into the flowable polymer. In this way the nanostructure of the master stamp is transferred to the flowable polymer.

It is advantageous if the master stamp and the support are arranged within a chamber sealed against the atmosphere/surroundings, the said chamber having a circumferential wall. In this way it is possible to be able to control the pressure conditions within the chamber so that the dipping of the master stamp in the liquid polymer occurs in a bubble-free manner.

In a development of the invention it is envisaged that the side of the support on which the nanostamping structure is to be applied is arranged parallel to the nanostructure surface of the master stamp. In this connection it is advantageous if the master stamp is arranged above the rigid support and the nanostructure surface of the master stamp is aligned downwardly in the direction of the rigid support. In the described configuration the flowable polymer is applied directly to the rigid support. The master stamp is moved relative to the rigid support, so that the nanostructure surface of the master stamp comes into contact with the flowable polymer.

Preferably the movement of the master stamp within the chamber takes place in the form of a translational movement to the support. In this connection the master stamp should where possible be driven up to the support. In this way an extremely thin polymer layer, preferably a PDMS layer, is formed. Due to this measure the flexibility of the nanostamping structure is achieved simply by the raised structure itself, and there are no flexible connections between the raised structures. The raised structures are joined to the fixed support exclusively in a vertical manner. The structures have no flexible connection with one another. In this way distortions and deformations no longer occur during a subsequent stamping process.

In order to be able to control accurately the movement of the master stamp and/or support, in a modification of the invention at least one measuring device is provided for measuring the position of the master stamp and/or support. Preferably the measuring device is arranged on the side of the master stamp facing away from the nanostructure surface of the master stamp, whereby the distance between the moving master stamp and the measuring device can be continuously measured.

In a modification of the invention at least one first vacuum line is provided for applying a vacuum to the support consisting, at least in a partial region, of porous material and/or material penetrated by channels. Preferably the vacuum line is arranged so that the vacuum can be applied to the side of the support facing away from the master stamp. By applying a vacuum the flowable polymer can be aspirated in a controlled manner into the pores and/or channels and capillaries of the support. In this way on the one hand the thickness of the resulting nanostamping structure is controlled. Furthermore, due to the aspiration process an intimate connection between the nanostamping structure located on the surface of the support and the support itself is produced by the flowable polymer that has penetrated into the support. The aspiration process is controlled in such a way that part of the flowable polymer remains on the support surface and is shaped by the nanostructure surface of the master stamp. It is also conceivable to apply, instead of or in addition to the vacuum, an excess pressure to the side of the support with the flowable polymer, in order to force the flowable polymer into the pores and channels of the support.

In an embodiment of the invention it is envisaged that the master stamp is sealed against the circumferential wall of the chamber and that at least a second vacuum and/or pressure line for applying a vacuum or a pressure is provided on the side of the master stamp lying opposite the nanostructure surface. The master stamp can be fixed by applying a vacuum. The master stamp can be displaced in the direction of the rigid support by applying a pressure. The master stamp is as it were formed as a piston that can move in a cylinder (chamber). Due to the uniform pressure distribution on the rear side of the master stamp a uniform movement of the master stamp without tilting is ensured.

In addition, in another embodiment of the invention it is envisaged that at least a third vacuum and/or pressure line is provided for applying a vacuum or a pressure in a region between the master stamp and the support. By means of this third vacuum and/or pressure line the movement of the master stamp and/or of the rigid support can additionally be controlled. At the same time it is possible to apply via this third vacuum line a pressure that forces the flowable polymer into the pores and channels of the support.

A bubble-free immersion of the master stamp in the liquid polymer is ensured by controlling the pressure conditions.

It is particularly advantageous if the device includes at least one adjustment marker stamp for introducing a three-dimensional adjustment marker into the side of the support facing away from the master stamp. In this connection it is convenient if the support can be placed on the adjustment marker stamp, i.e. the adjustment marker stamp is thus part of the holding device for the rigid support.

Preferably the adjustment marker stamp is formed as a ring, so that the support lies uniformly with a circumferential surface on the adjustment marker stamp. Adjustment marker structures are preferably provided at several defined positions on the ring spaced from one another in the circumferential direction. It is also conceivable to place the adjustment marker stamp on the support, or to press the support onto the adjustment marker stamp.

Advantageously there is provided at least a second application means for applying a flowable, hardenable polymer, in particular an elastomer, preferably a siloxane, specifically PDMS, to the adjustment marker stamp and/or to the side of the support facing away from the master stamp. It is however also possible to use the or the same application means for applying the flowable polymer for the production of the nanostamping structure as well as for applying the flowable hardenable polymer for the production of the adjustment markers. Preferably the application of the flowable polymer to the adjustment marker stamp is carried out before the insertion of the support.

The chemical composition of the polymer for the production of the adjustment markers can differ from the chemical composition for the production of the nanostamping structure. For the production of the adjustment markers it is conceivable to use fluorescing or colour-imparting substances or substances that change under specific physical circumstances.

In a modification of the invention at least one hardening device, preferably a heating means, is provided for hardening the nanostamping structure and/or the three-dimensional adjustment markers. Depending on the material that is used, instead of or in addition to a heating means a UV light unit for example can be used. Advantageously the adjustment markers and the nanostamping structure are hardened simultaneously in a joint hardening process. In this way a defined allocation of the adjustment markers to the nanostamping structure of the support is achieved.

In an embodiment of the invention the device includes at least one heating means, which is arranged on the side of the master stamp lying opposite the nanostructure surface. In addition or alternatively at least one further heating means can be provided on the side of the support facing away from the master stamp. In particular the hardening time is minimised and a more uniform temperature behaviour is ensured in the presence of two heating means.

According to an advantageous modification of the invention it is envisaged that the chamber comprises a first chamber section for the master stamp and a second chamber section, which can be sealed against the first chamber section, for the support, and that means for opening and closing the chamber by movement of at least one chamber section are provided. The second chamber section for the support forms the holding device for the support. After the two chamber sections have been moved apart the finished (ready-for-use) stamp can be removed and a new support can be inserted. Preferably the new support is placed on the adjustment marker stamp after a flowable polymer has been applied to the latter. The chamber is then closed, following which the application of the flowable polymer for the production of the nanostamping structure takes place. At the same time as the application of the flowable polymer or thereafter a relative movement between the support and the master stamp is executed. The aspiration of the flowable polymer into the porous support or support penetrated by channels preferably takes place at the same time. In this case flowable polymer is aspirated from the side of the support facing towards the master stamp as well as from the sides facing towards the adjustment marker stamp. After completion of the aspiration process the hardening of the flowable polymer takes place, preferably by means of two heating means.

One possible way of moving the first chamber section relative to the second chamber section is to execute a rotational movement between the chamber sections via a swivel linkage.

Another possibility is to move one chamber section in a translational manner towards and away from the respective other chamber section. For example, it is conceivable to execute the movement by means of a lift cylinder. Furthermore lateral guides can additionally be provided. A combined rotational-translational movement, for example via a four-linkage kinematic device, is also conceivable.

The present invention also provides a method for the production of a stamp with a nanostamping structure. In accordance with the method according to the invention it is envisaged that after the introduction of a support, in particular a porous support or one penetrated by channels, into a holding device, a hardenable polymer, in particular an elastomer, preferably a siloxane and specifically PDMS, is applied to the rigid support and/or to the nanostructure surface of a master stamp. The distance between the master stamp and the rigid support is then reduced, as a result of which the nanostructure surface of the master stamp dips into the flowable polymer. In a subsequent step the polymer is hardened, preferably by means of a heating means.

In order to create an optimal connection between the nanostamping structure to be produced from the polymer, and the support, in an embodiment of the invention a vacuum is applied to the support, whereby a partial amount of the polymer is sucked into the pores and channels of the support. In addition or alternatively a pressure can also be applied, so that the flowable polymer is forced into the pores and/or channels of the support.

During the procedure for producing the nanostamping structure, in another embodiment of the invention a three-dimensional adjustment marker is also introduced into the support, preferably into the side of the support facing away from the master stamp.

This adjustment marker is preferably likewise formed from a flowable polymer, in particular an elastomer, preferably a siloxane, specifically from PDMS. The hardening of the adjustment markers and of the nanostamping structure preferably takes place at the same time, so that a defined allocation between adjustment marker and nanostamping structure is achieved.

The deposition of substances to be embossed can take place both through the rear side of the porous support as well as on the front side of the stamp, and in particular both from the liquid and vapour phases.

Further advantages and expedient embodiments can be derived from the further claims, the description of the figures, and from the drawings. In particular essential method features can be derived from the description of the figures, in which:

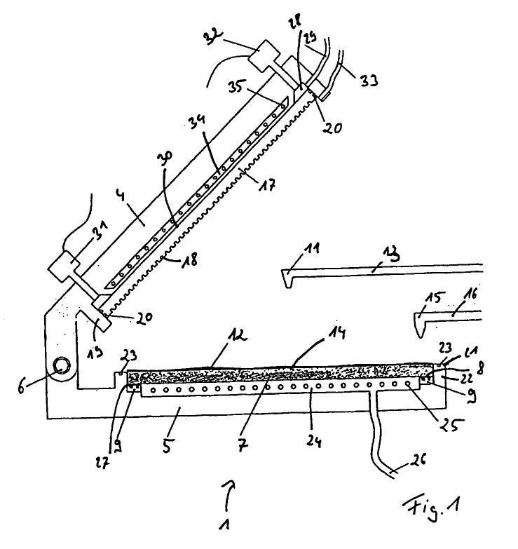

FIG. 1 shows a device for the production of a stamp with a nanostamping structure, with two chamber sections in the open state,

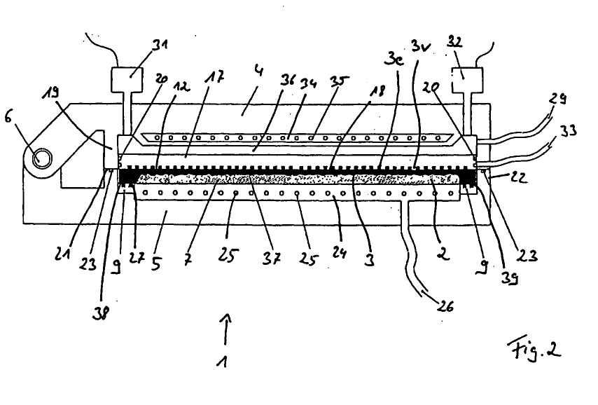

FIG. 2 shows the device according to FIG. 1 with closed chamber sections,

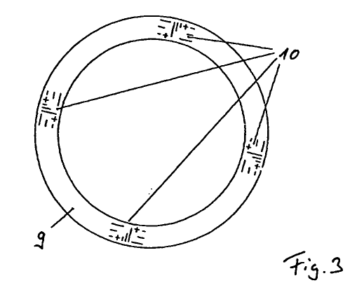

FIG. 3 shows an adjustment marker stamp formed as a ring with adjustment marker structures, and

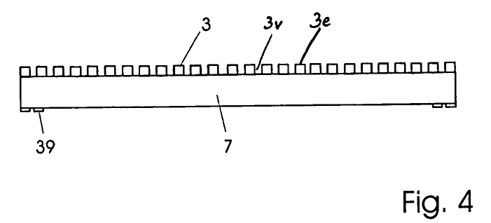

FIG. 4 shows a stamp.

In the figures identical structural parts as well as structural parts having the same function are provided with the same reference numerals.

FIG. 1 shows a device 1 for the production of a stamp 2 with a nanostructure stamping structure 3 (see FIG. 2), in which the nanostamping structure 3 comprises raised structures 3e and depressions 3v adjacent to the raised structures 3e.

The device 1 comprises first and second chamber sections 4, 5, wherein the two chamber sections 4, 5 are articulatedly joined to one another via a swivel linkage 6. The lower, second chamber section 5 is horizontally aligned and serves as a holding device for a support 7 for the nanostamping structure 3 to be applied.

The support 7 lies with its circumferential edge region 8 on an annular adjustment master stamp 9. The adjustment master stamp 9 is shown in plan view in FIG. 3. As can be seen from FIG. 3, the adjustment marker stamp 9 comprises a plurality of adjustment marker structures 10, distributed over the circumference, for introducing corresponding adjustment markers on the support 7 arranged thereabove.

In addition the device comprises a first application means designed as a nozzle 11, for applying flowable poly(dimethylsiloxane) (PDMS) 12 to the porous support 7. The nozzle 11 is connected to a line 13. A metering device (not shown) for the metered application of the flowable PDMS to an upper side 14 of the porous, rigid support is associated with the line 13.

A second application means, likewise formed as a nozzle 15, for applying PDMS to the upper side of the adjustment marker stamp 9 is located underneath the nozzle 11 and associated line 13. In the illustrated example of implementation the application of PDMS 27 to the adjustment marker stamp 9 takes place before the insertion of the porous support 7 in the second chamber section 5. The second nozzle 15 is connected to a line 16, which leads to a metering device and pump (not shown).

A master stamp 17 with a nanostructure surface 18 is arranged in the first chamber section 4. The master stamp 17 is sealed against a circumferential wall 19 of the first chamber section 4 by means of two O-rings 20 arranged above one another. The O-rings 20 are designed in such a way that the master stamp 17 can be moved in a translational manner along the circumferential wall 19.

A circumferential annular seal 23 is arranged on the upper side 21 of a circumferential wall 22 of the second chamber section. This provides a sealing connection between the first chamber section 4 and the second chamber section 5, as is illustrated in FIG. 2.

A cavity 24 extending almost over the whole surface area of the support 7 is provided underneath the porous support 7 and laterally within the annular adjustment master stamp 9. The upper side of the cavity 24 is formed by the porous support 7. A plurality of spaced-apart heating coils 25 are arranged within the cavity 24. These serve for the subsequent hardening of the PDMS 27 applied to the adjustment master stamp 9 as well as for the hardening of the PDMS 12 applied to the support 7 through the nozzle 11.

A first vacuum line 26, with which a reduced pressure can be generated in the cavity 24, terminates in the cavity 24. This reduced pressure acts on the porous support 7, whereby a partial amount of the PDMS 12 applied to the latter as well as a partial amount of the PDMS 27 applied to the adjustment marker stamp 9 can be sucked into the pores of the rigid support.

In the first chamber section 4 a circumferential annular groove 28 is incorporated above the master stamp 17. A second vacuum/pressure line 29 terminates in this annular groove. Via the line 29 a reduced pressure as well as an excess pressure can be exerted on the side 30 facing away from the support 7. When a reduced pressure is applied the master stamp 17 is held in the first chamber section 4. Under normal pressure or if the region behind the side 30 of the master stamp 17 is charged with excess pressure, the master stamp 17 moves in a translational manner in the direction of the rigid support 7.

Two spaced-apart measuring devices 31, 32 terminate in the annular groove 28, by means of which the position of the master stamp 17 and thus the distance between the nano-structure surface 18 of the master stamp 17 and the support 7 can be determined.

A third vacuum/pressure line 33 is arranged spaced from the second vacuum/pressure line 29, the third line terminating in a region between the master stamp 17 and the support 7.

Both vacuum/pressure lines 29, 33 are led laterally through the circumferential wall 19 of the first chamber section 4. By means of the third vacuum/pressure line 33 a reduced pressure and/or an excess pressure can be generated in the region between the master stamp 17 and the support 7.

Above the master stamp 17 a second cavity 34 is introduced within the first chamber section 4. A plurality of spaced-apart heating coils 35 for hardening the applied PDMS are located in this second cavity 34.

In FIG. 2 the chamber 36 formed from the first chamber section 4 and the second chamber section 5 is closed and is sealed against the atmosphere/surroundings by means of the annular seal 23.

Both nozzles 11, 15 together with their lines 13, 16 are swivelled out from the region within the chamber 36. A vacuum is applied to the cavity 24 via the vacuum line 26, whereby a partial amount 37 of the PDMS 12 applied to the support 7 is sucked into the pores of the support 7. In addition a partial amount 38 of the PDMS 27 applied to the adjustment master stamp 9 is sucked into the pores of the support 7.

The vacuum/pressure line 29 is subjected to normal pressure. The master stamp is driven in a translational manner up to the support 7, the position of the master stamp being determined by the measuring devices 31, 32. The third vacuum/pressure line 33 no longer has any function in the state illustrated in FIG. 2. The line 33 is sealed from the circumferential side of the master stamp 17.

The method for producing the stamp is described hereinafter.

To start with, the two chamber sections 4, 5 are open, as shown in FIG. 1. PDMS 27 is now applied through the nozzle 15 to the upper side 10, provided with adjustment marker structures 10, of the annular adjustment master stamp 9. The porous support 7 is then placed on the annular adjustment master stamp 9 coated with PDMS 27. A closed cavity is thereby formed underneath the support 7. Following this the upper side 14 of the support 7 is coated with liquid PDMS 12 via the nozzle 11 and line 13 connected thereto.

In the following step the nozzles 11, 15 together with the associated lines 13, 16 are swivelled out from the region between the first chamber section 4 and the second chamber section 5.

The chamber 36 is then closed by swivelling the first chamber section 4 about the swivel linkage 6. A motor drive (not shown) can be provided for this purpose. The circumferential wall 10 of the first chamber section 4 lies on the circumferential wall 22 of the second chamber section 5. Sealing is effected via the annular seal 23 on the upper side 21 of the circumferential wall 22 of the second chamber section 5.

A vacuum is applied to the second vacuum/pressure line 29, in order to hold the master stamp 17 in the upper position illustrated in FIG. 1. After a predetermined time a vacuum is also applied to the lines 26, 33. Due to the charging of the cavity 24 with reduced pressure via the vacuum line 26, a partial amount 37 of the PDMS 12 as well as a partial amount 38 of the PDMS 27 are sucked into the pores of the rigid support 7. The PDMS thus adheres within the stamp material.

After an adjustable evacuation time the second vacuum/pressure line 29 is connected to atmospheric pressure. At a later time the third vacuum/pressure line 33 is also connected to atmospheric pressure. The master stamp 17 moves in the direction of the support 7, whereby the nanostructure surface 18 dips into the PDMS 12 located on the upper side 14 of the support 7. Preferably the master stamp 17 drives up to the support 7, in order to maintain as thin a nanostamping structure of PDMS as possible. The position of the master stamp 17 is determined by the measuring devices 31, 32. The measurement result serves as control quantity for a movement control unit (not shown), which also controls the charging of the vacuum/pressure lines 26, 29 and 33. Due to the fact that the nanostructure surface 18 of the master stamp 17 dips into the liquid PDMS 12, the nanostructure is transferred without formation of bubbles into the liquid PDMS 12 on the upper side 14 of the support 7. At the same time excess PDMS 37 is sucked into the porous support 7. After the aspiration of the desired amount of PDMS 37 into the rigid support 7 and/or after a predetermined position of the master stamp 17 has been reached, the hardening process by means of the heating coils 25, 35 begins. The nanostamping structure 3 of PDMS as well as the adjustment markers 39 on the side of the support 7 facing towards the nanostamping structure 3 thereby hardens. Due to the simultaneous hardening a defined allocation of the adjustment markers 39 to the nanostamping structure 3 is achieved.

After the hardening process the first chamber section 4 is swivelled about the linkage 6 to the open position, following which the finished stamp, consisting of support 7, nanostamping structure 3 as well as adjustment markers 39 can be removed.

The device is now ready for the production of a further, large surface area nanostructure stamp.

A large surface area stamp 2 according to the invention with a nanostamping structure 3 comprising raised structures 3e as well as depressions 3v adjacent to the raised structures 3e, and with a porous support 7 as well as adjustment markers 39, is shown in FIG. 4. The upper side and the lower side of the stamp 2 are formed flat and parallel.

Stamp with a nanostamping structure as well as device and method for the production thereof.

### LIST OF REFERENCE NUMERALS

1 Device
2 Stamp
3 Nanostamping structure
3e Raised structures
3v Depressions
4 First chamber section
5 Second chamber section
6 Swivel linkage
7 Support
8 Edge region
9 Adjustment marker stamp
10 Adjustment marker structure
11 First nozzle (first application means)
12 PDMS
13 Line
14 Upper side of the support
15 Second nozzle (second application means)
16 Line
17 Master stamp
18 Nanostructure surface
19 Circumferential wall
20 O-rings
21 Upper side
22 Circumferential wall
23 Annular seal
24 Cavity
25 Heating coil
26 First vacuum line
28 Annular groove
29 Second vacuum/pressure line
30 Side
31 Measuring device
32 Measuring device
33 Third vacuum/pressure line
34 Second cavity
35 Heating coil
36 Chamber
37 Partial amount
38 Partial amount
39 Adjustment markers

1. Stamp (2) with a nanostamping structure (3) for the introduction and/or application of nanostructures into/on components, wherein the stamp (2) comprises a rigid support (7) for the nanostamping structure (3) and the nanostamping structure (3) is joined to the support (7), and wherein the nanostamping structure (3) is formed from raised structures (3e) and depressions (3v) adjacent to the raised structures (3e), characterised in that the depressions (3v) are formed extending predominantly up to the rigid support (7).

2. Stamp according to claim 1, characterised in that the nanostamping structure (3) consists of a hardened polymer, in particular an elastomer, preferably a siloxane, specifically poly(dimethylsiloxane) (PDMS) (12).

3. Stamp according to claim 1, characterised in that the support (7) consists, at least in a partial region, of porous material and/or material penetrated by channels.

4. Stamp according to claim 3, characterised in that the support (7) consists, at least in partial regions, of ceramic material, preferably sintered ceramic material.

5. Stamp according to claim 3, characterised in that a partial amount (37) of the hardened polymer is forced into the pores and/or the channels of the rigid support (7).

6. Stamp according to one of the preceding claims, characterised in that the stamp (2) comprises adjustment means (39).

7. Stamp according to claim 6, characterised in that the adjustment means (39) are arranged on a side of the support (7) lying opposite the nanostamping structure (3).

8. Stamp according to claim 6, characterised in that the adjustment means (39) are formed as three-dimensional adjustment markers (39).

9. Stamp according to claim 8, characterised in that the adjustment markers (39) consist of a hardened polymer, in particular an elastomer, preferably a siloxane, and specifically poly(dimethylsiloxane) (PDMS) (27).

10. Stamp according to claim 8, characterised in that the adjustment markers (39) consist of a different material to the nanostamping structure (3).

11. Device for the production of a stamp (2) with a nanostamping structure (3), for the introduction and/or application of nanostructures into/on components wherein the device (1) includes the following structural parts:
a receiving means (5) for receiving a rigid support (7);
at least one master stamp (17) with a nanostructure surface (18), movable relative to the rigid support (7);
at least one application means (11) for applying a flowable, hardenable polymer, in particular an elastomer, preferably a siloxane and specifically polymer(dimethylsiloxane) (PDMS) (12) to the support (7) and/or to the master stamp (17);
raised structures (3e) as well as depressions (3v) adjacent to the raised structures (3e) which can be applied via the correspondingly configured nanostructure surface (18) by means of the device, characterised in that the nanostructure surface (18) is designed so that it can be driven directly up to the rigid support (7).

12. Device according to claim 11, characterised in that a sealable chamber (36) for the master stamp (17) and the rigid support (7) is provided with a circumferential wall (19, 22).

13. Device according to claim 11, characterised in that the side (14) of the support (7) on which the nanostamping structure (3) is applied can be arranged parallel to the nanostructure surface (18) of the master stamp (17), preferably in such a way that the master stamp (17) is arranged above the rigid support (7) and the nanostructure surface (18) of the master stamp (17) is aligned downwardly in the direction of the rigid support (7).

14. Device according to claim 11, characterised in that the master stamp (17) can be moved within the chamber (36) in a translational manner to the support (7), preferably up to the support (7).

15. Device according to claim 11, characterised in that one or more measuring devices (31, 32) is/are provided for measuring the position of the master stamp (17) and/or of the support (7).

16. Device according to claim 11, characterised in that at least a first vacuum line (26) for applying a vacuum to the support (7) consisting at least in a partial region of porous material and/or material penetrated by channels, is provided preferably on the side of the support (7) facing away from the master stamp (17).

17. Device according to one of claims 12 to 16, characterised in that the master stamp (17) is sealed against the circumferential wall (19, 22) of the chamber (36) and that at least a second vacuum and/or pressure line (29) is provided for applying a vacuum or an excess pressure to the side of the master stamp (17) lying opposite the nanostructure surface (18).

18. Device according to claim 17, characterised in that at least a third vacuum and/or pressure line (33) is provided for applying a vacuum or an excess pressure in a region between the master stamp (17) and the support (7).

19. Device according to claim 11, characterised in that at least one adjustment marker stamp (9) is provided for introducing a three-dimensional adjustment marker (39) into the side of the support (7) facing away from the master stamp (17).

20. Device according to claim 19, characterised in that the adjustment marker stamp (9) is designed as a ring.

21. Device according to claim 19, characterised in that at least a second application means (15) is provided for applying a flowable, hardenable polymer, in particular an elastomer, preferably a siloxane, specifically poly(dimethylsiloxane) (PDMS) (27) to the adjustment master stamp (9) and/or to the side of the support (7) facing away from the master stamp (17).

22. Device according to claim 11, characterised in that at least one hardening device (25, 35), preferably a heating means (25, 35), is provided for hardening the nanostamping structure (3) and/or the three-dimensional adjustment markers (39).

23. Device according to claim 22, characterised in that at least one heating means (25, 35) is provided on the side of the master stamp (17) lying opposite the nanostructure surface (18) and/or that at least one heating means (25, 35) is provided on the side of the support (7) facing away from the master stamp (17).

24. Device according to claim 12, characterised in that the chamber (36) comprises a first chamber section (4) for the master stamp (17) and a second chamber section (5), which can be sealed with respect to the first chamber section (4), for the support (7), and that means are provided for opening and closing the chamber (36) by moving at least one chamber section (4, 5).

25. Device according to claim 24, characterised in that both chamber sections (4, 5) are articulatedly connected to one another via a swivel linkage (6).

26. Device according to one of claims 24 and 25, characterised in that at least one chamber section (24, 25) can be moved in a translational manner to the respective other chamber section (25, 24).

27. Method for producing a stamp (2) with a nanostamping structure (3) for the introduction and/or application of nanostructures into/on components, the method comprises the following process steps:
application of a flowable, hardenable polymer, in particular an elastomer, preferably a siloxane, specifically poly(dimethylsiloxane) (PDMS) (12) to a rigid support (7) and/or to a master stamp (17) with a nanostructure surface (18);
reducing the distance between the master stamp (17) and the rigid support (7) and thereby introducing the nanostructure of the master stamp (17) into the flowable polymer (12) to produce a nanostamping structure (3) with raised structures (3e) and depressions (3v) adjacent to the raised structures (3e), until there is an at least partial contacting of the master stamp (17) with the rigid support (7);
hardening the polymer (12).

28. Method according to claim 27, characterised in that a vacuum is applied to the support (7) consisting at least in a partial region of porous material and/or that is penetrated by channels, a partial amount (37) of the polymer (12) thereby being aspirated into the support (7).

29. Method according to one of claims 27 and 28, characterised in that a three-dimensional adjustment marker (39) is introduced into the support (7), preferably into the side of the support (7) facing away from the master stamp (17).

30. Method according to claim 29, characterised in that the three-dimensional adjustment markers (39) and the nanostamping structure (3) are simultaneously hardened.
